(19) United States
(12) Patent Application Publication
(10) Pub. No.: US 2024/0339972 A1
(43) Pub. Date: Oct. 10, 2024

(54) RADIO FREQUENCY CIRCUIT

(71) Applicant: RichWave Technology Corp., Taipei (TW)

(72) Inventors: Chia-Jung Yeh, Taipei (TW); Chih-Sheng Chen, Taipei (TW)

(73) Assignee: RichWave Technology Corp., Taipei (TW)

(21) Appl. No.: 18/519,095

(22) Filed: Nov. 27, 2023

(30) Foreign Application Priority Data
Apr. 10, 2023 (TW) 112113326

(51) Int. Cl. H03F 3/24; H03K 17/56; H04B 1/40

(52) U.S. Cl. CPC H03F 3/245; H03K 17/56; H04B 1/40; H03F 2200/294; H03F 2200/451

(57) ABSTRACT

A radio frequency circuit is provided. The radio frequency circuit includes a first terminal, a second terminal, a power amplifier, and a coupling circuit. The power amplifier is coupled between the first terminal and the second terminal. The power amplifier is configured to receive a first signal. The coupling circuit includes a first coupling terminal, a second coupling terminal, and at least one transistor. The first coupling terminal is coupled to the power amplifier and the second terminal. The at least one transistor is connected in series between the first coupling terminal and the second coupling terminal. In a coupling mode, the at least one transistor is in an at least partial cut-off state, and the at least one transistor provides a coupling signal at the second coupling terminal through capacitive coupling. The first signal is controlled according to the coupling signal.

### CROSS-REFERENCE TO RELATED APPLICATION

This application claims the priority benefit of Taiwan application serial no. 112113326, filed on Apr. 10, 2023. The entirety of the above-mentioned patent application is hereby incorporated by reference herein and made a part of this specification.

### BACKGROUND

### Technical Field

The disclosure relates to a circuit structure technology for radio communications, and more particularly to a radio frequency circuit.

### Description of Related Art

A radio frequency circuit may transmit and receive a radio signal through an antenna apparatus. If the power intensity of the signal provided by the radio frequency circuit to the antenna apparatus can be known, the radio frequency circuit may use the power intensity of the feedback for power control.

Conventional radio frequency circuits may control the power through a loopback path formed by a coupling line between the output terminal of the antenna and the radio frequency circuit. However, the aforementioned coupling line technology is prone to the problem of coupling directivity, and will increase power loss and wiring length.

### SUMMARY

The disclosure provides a radio frequency circuit, which may reduce the power loss and wiring length of the coupling circuit, and provides programmable loopback power control.

The radio frequency circuit of the disclosure includes a first terminal, a second terminal, a power amplifier, and a coupling circuit. The power amplifier is coupled between the first terminal and the second terminal, and configured to receive a first signal. The coupling circuit includes a first coupling terminal, a second coupling terminal, and at least one transistor. The first coupling terminal is coupled to the power amplifier and the second terminal. The at least one transistor is connected in series between the first coupling terminal and the second coupling terminal. In a coupling mode, the at least one transistor is in a partial cut-off state, and the at least one transistor provides a coupling signal at the second coupling terminal through capacitive coupling. The first signal is controlled according to the coupling signal.

Based on the above, the radio frequency circuit of the disclosure may use at least one transistor as a coupling circuit between the first coupling terminal and the second coupling terminal. The at least one transistor may be used as a shut-off capacitor in the cut-off state. Accordingly, the coupling circuit may achieve capacitive coupling in series by setting the at least one transistor to a state where at least a portion is cut off. In this way, the coupling circuit of the disclosure may replace the conventional coupling line, reducing the wiring length and power loss.

### BRIEF DESCRIPTION OF THE DRAWINGS

FIG. 1 is a schematic view of a radio frequency circuit according to the first embodiment of the disclosure.

FIG. 2 shows a relationship between output power of a coupling signal and output power of a signal according to the first embodiment of the disclosure.

FIG. 3 is a schematic view of a radio frequency circuit according to the second embodiment of the disclosure.

FIG. 4 is a schematic view of a radio frequency circuit according to the third embodiment of the disclosure.

FIG. 5 is a schematic view of a radio frequency circuit according to the fourth embodiment of the disclosure.

FIG. 6 is a schematic view of a radio frequency circuit according to the fifth embodiment of the disclosure.

FIG. 7 is a schematic view of a radio frequency circuit according to the sixth embodiment of the disclosure.

FIG. 8 is a schematic view of a radio frequency circuit according to the seventh embodiment of the disclosure.

FIG. 9 is a schematic view of a radio frequency circuit according to the eighth embodiment of the disclosure.

FIG. 10 is a schematic view of a radio frequency circuit according to the ninth embodiment of the disclosure.

### DESCRIPTION OF THE EMBODIMENTS

Some embodiments of the disclosure accompanied with the drawings will now be described in detail. These examples are only a portion of the disclosure and do not disclose all possible embodiments of the disclosure. More precisely, these embodiments are only examples within the scope of the patent application of the disclosure.

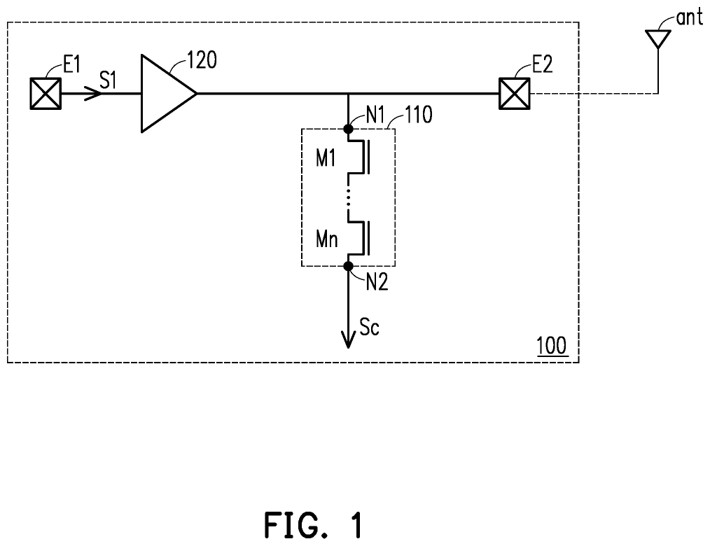

FIG. 1 is a schematic view of a radio frequency circuit 100 according to the first embodiment of the disclosure. The radio frequency circuit 100 in FIG. 1 may be used, for example, in a power amplifier module (PAM), or in a front-end module (FEM). Referring to FIG. 1, the radio frequency circuit 100 includes a terminal E1, a terminal E2, a coupling circuit 110, and a power amplifier 120. The power amplifier 120 is coupled between the terminal E1 and the terminal E2. The coupling circuit 110 is coupled to the power amplifier 120 and the terminal E2. Specifically, an input terminal of the power amplifier 120 is coupled to the terminal E1, and an output terminal of the power amplifier 120 is coupled to the coupling circuit 110 and the terminal E2 at the same time. The power amplifier 120 may be used to receive a signal S1 from the terminal E1. The coupling circuit 110 includes a coupling terminal N1, a coupling terminal N2, and transistors M1˜Mn. The coupling terminal N1 is coupled to the power amplifier 120 and the terminal E2. The transistor amount of the transistors M1˜Mn may be one or more than one. The transistor amount of the transistors M1˜Mn in this embodiment is implemented by, for example, at least 5, and the disclosure is not limited thereto.

In a coupling mode, the transistors M1˜Mn are in an at least partial cut-off state, and the transistors M1˜Mn provides a coupling signal Sc at the second coupling terminal N2 through capacitive coupling. Specifically, each of the transistors M1˜Mn may be used as a shut-off capacitor in the cut-off state. The “partial cut-off state” may be used to indicate that at least one of the transistors M1˜Mn is in a cut-off state (e.g., a shut-off state), and the transistor in the cut-off state may be used as a shut-off capacitor. Alternatively, in response to the amount of the transistors M1˜Mn being 1, that is, only the transistor M1 is in use, the “partial cut-off state” may be used to indicate that the transistor M1 is not completely turned on, but at least a portion is cut off. If the transistors M1˜Mn are in the partial cut-off state, the coupling circuit 110 may provide the coupling signal Sc at the coupling terminal N2 through capacitive coupling. Further, the signal S1 may be controlled according to the coupling signal Sc, and the signal S1 may be output to an antenna ant through the terminal E2. On the other hand, each of the transistors M1˜Mn may be regarded as a turned-on resistor in a fully turned-on state.

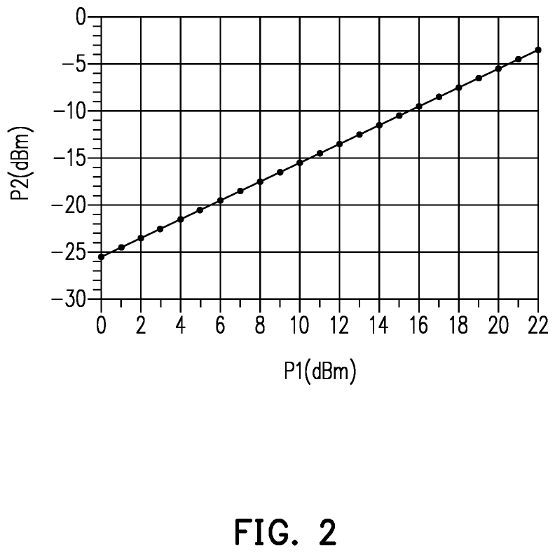

FIG. 2 shows a relationship between output power of the coupling signal Sc and output power of the signal S1 according to the first embodiment of the disclosure. In other words, FIG. 2 is a diagram generated by simulation showing the relationship between the output power of the coupling signal Sc and the output power of the signal S1 of the radio frequency circuit 100 in FIG. 1. Referring to FIG. 1 and FIG. 2, output power P2 of the coupling signal Sc is positively correlated with output power P1 of the signal S1. Specifically, in the coupling mode, the transistors M1˜Mn in the coupling circuit 110 may couple a portion of the signal S1 to the coupling circuit 110 through the coupling terminal N1 through capacitive coupling. Moreover, the coupling circuit 110 provides the coupling signal Sc at the coupling terminal N2. In the embodiment shown in FIG. 2 (i.e., the first embodiment), the output power P1 of the signal S1 is attenuated by 25.5 (dBm) after passing through the coupling circuit 110. In other words, the output power P1 of the signal S1 is 25.5 (dBm) higher than the output power P2 of the coupling signal Sc. In this way, the coupling signal Sc may be used to detect the output power of the signal S1 correspondingly. It should be noted that the output power P1 should be referred to the output power of the amplified signal S1.

In the radio frequency circuit 100, since the conventional coupling line is replaced by the coupling circuit 110, the wiring used by the coupling line may be omitted, and the coupling directivity issue and power loss caused by the use of the coupling line may also be reduced. In addition, in the case of the radio frequency circuit 100 being applied to a front-end module, the integrated circuit used together does not need to have a pin for the coupling line. The coupling circuit 110 may share the pin with the output terminal of the radio frequency signal. As a result, one pin may be omitted, making the pin configuration more flexible, and further reducing the volume of the integrated circuit package.

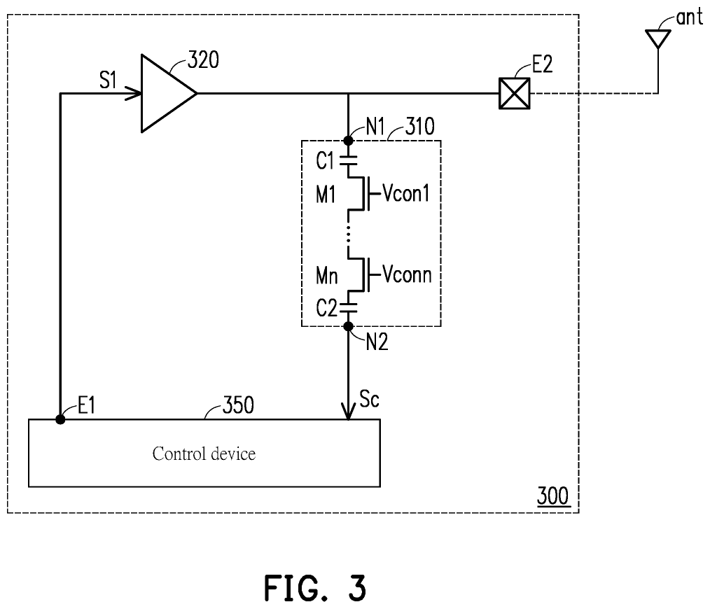

FIG. 3 is a schematic view of a radio frequency circuit 300 according to the second embodiment of the disclosure. The radio frequency circuit 300 in FIG. 3 may be a power amplifier control system. Referring to FIG. 3, in addition to the circuit structure in FIG. 1, the radio frequency circuit 300 further includes a capacitor C1, a capacitor C2, and a control device 350. The control device 350 is coupled between the terminal E1 and the coupling terminal N2. The capacitor C1 is connected in series between the coupling terminal N1 and the transistors M1˜Mn. The capacitor C2 is connected in series between the coupling terminal N2 and the transistors M1˜Mn. The coupling circuit 310 may absorb or release current from the external through the charge/discharge of the capacitor C1 and the capacitor C2, so that the transistors M1˜Mn inside the coupling circuit 310 is not affected. In the embodiment of FIG. 3, the terminal E1 is, for example, a signal input terminal, and the terminal E2 is, for example, a signal output terminal.

Taking FIG. 3 as an example, the control device 350 may receive the coupling signal Sc, and output the signal S1 to a power amplifier 320 through the terminal E1 according to the coupling signal Sc, and the output power of the signal S1 is controlled according to the coupling signal Sc. In the second embodiment of FIG. 3, the output power of the signal S1 is positively correlated with the output power of the coupling signal Sc. The higher the output power of the signal S1 output from the control device 350 to the power amplifier 320 through the terminal E1 is, the higher the output power of the coupling signal Sc received by the control device 350 is. In the coupling mode, a portion of the signal S1 pass through the coupling circuit 310 from the coupling terminal N1, and the coupling signal Sc is output to the control device 350 from the coupling terminal N2. The control device 350 may adjust the output power of the signal S1 according to the received coupling signal Sc, and the control device 350 then outputs the adjusted signal S1 to the power amplifier 320 through the terminal E1.

Next, after the output power of the signal S1 is amplified by the power amplifier 320, the signal S1 is output through the terminal E2. Specifically, the output power of the signal S1 may be amplified by the power amplifier 320, and the amplified signal S1 is then output to the antenna ant through the terminal E2. In this way, the radio frequency circuit 300 may adjust the output power of the signal S1 output to the antenna ant through the coupling signal Sc, which means that the radio frequency circuit 300 may use the power intensity of the feedback to perform power control.

To further illustrate, in the coupling mode, a cut-off degree of each of the transistors M1˜Mn is changed according to corresponding control voltages Vcon1˜Vconn to adjust the output power of the coupling signal Sc. Specifically, the coupling circuit 310 may, for example, adjust the value of the control voltages Vcon1˜Vconn through the control device 350 to adjust the impedance of the corresponding transistors M1˜Mn, so that the coupling circuit 310 may adjust the output power of the coupling signal Sc. In this way, the coupling circuit 310 may provide programmable loopback power control by adjusting the control voltages Vcon1˜Vconn corresponding to the transistors M1˜Mn.

It is worth mentioning that each of the transistors M1˜Mn may be used as a shut-off capacitor in the cut-off state. Thus, in the coupling mode, at least one of the transistors M1˜Mn has to be in the cut-off state (i.e., at least one of the transistors M1˜Mn is used as a shut-off capacitor). In this way, the coupling circuit 310 may provide the coupling signal Sc at the coupling terminal N2 through capacitive coupling.

In an embodiment, an amount of the transistors M1˜Mn is plural, and each of the transistors is controlled according to individual independent control voltages Vcon1˜Vconn. Specifically, in the coupling mode, N transistors among the transistors are cut off. N is a positive integer greater than 1, and the output power of the coupling signal Sc is changed based on N. Since each of the transistors M1˜Mn may be used as a shut-off capacitor in the cut-off state, and each of the transistors M1˜Mn may be used as a turned-on resistor in a fully turned-on state, the cut-off state of the transistors M1˜Mn may be respectively controlled by the independent control voltages Vcon1˜Vconn. In this way, the output power of the coupling signal Sc may be changed by adjusting the value of N (i.e., adjusting the amount of the transistor in the cut-off state). In other words, the coupling circuit 110 may turn on or off corresponding transistors M1˜Mn through the control voltages Vcon1˜Vconn to control the coupling signal Sc more simply and variously, thereby providing the programmable loopback power control. In addition, in an embodiment, the amount of the transistors M1˜Mn is at least 5, and the disclosure is not limited thereto.

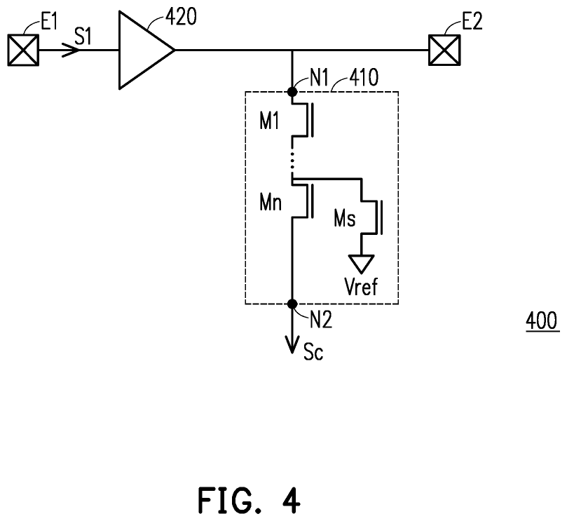

FIG. 4 is a schematic view of a radio frequency circuit 400 according to the third embodiment of the disclosure. The radio frequency circuit 400 of FIG. 4 may be, for example, applied to a front-end module. In addition to the circuit structure in FIG. 1, the radio frequency circuit 400 further includes a shunt transistor Ms. A first terminal of the shunt transistor Ms is coupled between the coupling terminal N1 and the coupling terminal N2, and a second terminal of the shunt transistor Ms is coupled to a reference voltage terminal Vref, which is, for example, a ground terminal.

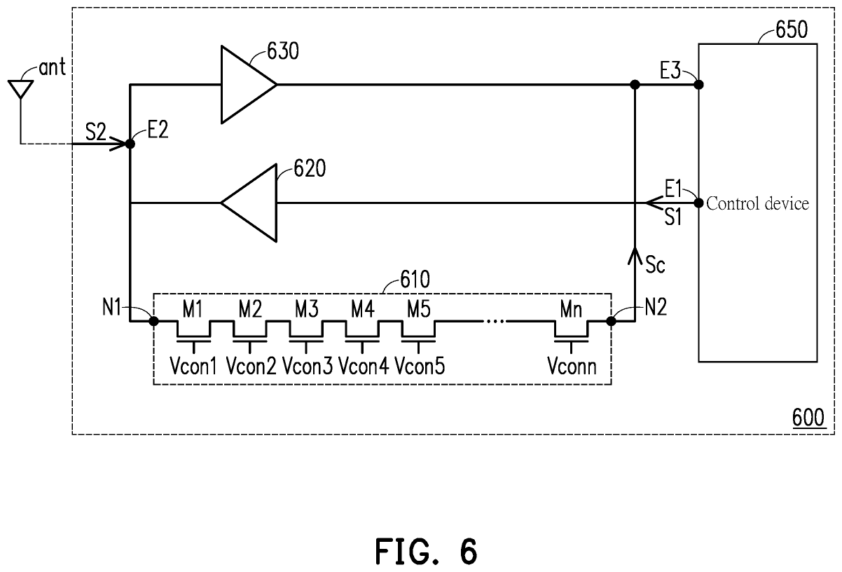

In the coupling mode, the shunt transistor Ms is cut off. Specifically, the radio frequency circuit 400 in FIG. 4 may also be used with a control device 650 in a front-end control system in the embodiment of FIG. 6. Referring to FIG. 4 and FIG. 6 together, the transistors M1˜Mn may couple a portion of the signal S1 to the coupling circuit 410 through capacitive coupling and provide the coupling signal Sc to the control device 650 from the coupling terminal N2. The control device 650 outputs the signal S1 to the power amplifier 620 through the terminal E1 according to the received coupling signal Sc. In this case, the portion of the signal S1 coupled by the transistors M1˜Mn is used to provide the coupling signal Sc, and the portion of the signal S1 is not transmitted to the reference voltage terminal Vref through the shunt transistor Ms.

In a shut-off mode, the transistors M1˜Mn are all in the cut-off state, and the shunt transistor Ms is turned on. Specifically, for example, the control device 650 may be used to control the transistors M1˜Mn to be in the cut-off state and control the shunt transistor Ms to be in the turned-on state. In this case, the radio frequency circuit 400 does not require the coupling signal Sc provided by the coupling circuit 410 to adjust the output power of signal S1. Thus, the shunt transistor Ms may be turned on and transmits the current flowing through the coupling circuit 410 to the reference voltage terminal Vref. In this way, the coupling circuit 410 may be prevented from transmitting the coupling signal Sc to the control device 650 through the coupling terminal N2, thereby increasing the isolation of the signal.

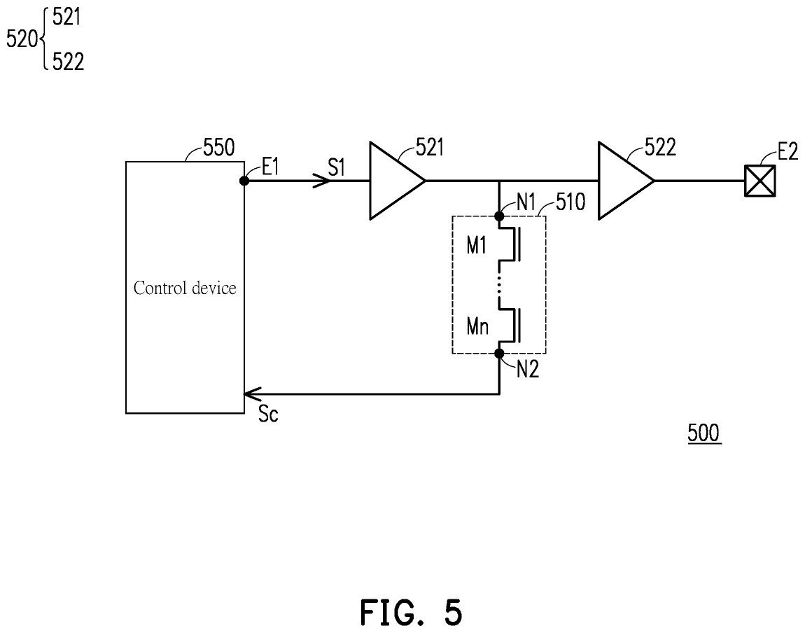

FIG. 5 is a schematic view of a radio frequency circuit 500 according to the fourth embodiment of the disclosure. The radio frequency circuit 500 in FIG. 5 may be, for example, a front-end control system. Referring to FIG. 5, a power amplifier 520 of the radio frequency circuit 500 includes a first stage amplifier 521 and a second stage amplifier 522. The coupling terminal N1 of the coupling circuit 510 is coupled between the first stage amplifier 521 and the second stage amplifier 522. In an embodiment, the power amplifier 520 may include multiple stages amplifiers, and each of the stages amplifiers has a corresponding output terminal. In the coupling mode, the transistors M1˜Mn of the coupling circuit 510 are in an at least partial cut-off state, and a portion of the signal S1 may be coupled by an output terminal of the first stage amplifier 521 through capacitive coupling. Moreover, the coupling signal Sc is provided from the coupling terminal N2 to the control device 550. Next, the control device 550 may adjust the output power of the signal S1 according to the received coupling signal Sc, and the control device 550 then outputs the adjusted signal S1 to the first stage amplifier 521 and the second stage amplifier 522 through the terminal E1 for amplification. Finally, the amplified signal S1 is output through the terminal E2.

FIG. 6 is a schematic view of a radio frequency circuit according to the fifth embodiment of the disclosure. A radio frequency circuit 600 in FIG. 6 may be, for example, a front-end control system. Referring to FIG. 6, in addition to the circuit structure in FIG. 1, the radio frequency circuit 600 further includes a terminal E3, a low noise amplifier 630, and a control device 650. The low noise amplifier 630 is coupled between the terminal E2 and the terminal E3. In this embodiment, the terminal E1 is, for example, a signal input terminal of the power amplifier 620. The terminal E3 is, for example, a signal output terminal of the low noise amplifier 630. The terminal E2 is, for example, a common terminal of signals.

In the embodiment of FIG. 6, in a low noise amplification mode, the transistors M1˜Mn are cut off, the signal S2 is transmitted from the terminal E2 to the low noise amplifier 630, the low noise amplifier 630 is enabled, and the power amplifier 620 is disabled. Specifically, the signal S2 input by the antenna ant may be transmitted to the low noise amplifier 630 through the terminal E2, the low noise amplifier 630 is enabled, and the signal S2 is amplified by the low noise amplifier 630. Moreover, the amplified signal S2 is output to a receiving terminal (i.e., the terminal E3) of the control device 650 to ensure the receiving quality. On the other hand, in the coupling mode, the transistors M1˜Mn of the coupling circuit 610 are in an at least partial cut-off state, and a portion of the signal S1 may be coupled by an output terminal of the power amplifier 620 through capacitive coupling. The coupling signal Sc is provided from the coupling terminal N2 to the terminal E3, the low noise amplifier 630 is disabled, and the power amplifier 620 is enabled. Next, the control device 650 may adjust the output power of the signal S1 according to the coupling signal Sc, and the control device 650 then outputs the adjusted signal S1 to the power amplifier 620 through the terminal E1 for amplification. Finally, the amplified signal S1 is output to the antenna ant through the terminal E2. In this way, the radio frequency circuit 600 may adjust the output power of the signal S1 output to the antenna ant through the coupling signal Sc, which means that the radio frequency circuit 600 may use the power intensity of the feedback to perform power control. In addition, the cut-off degree of each of the transistors M1˜Mn is changed according to the control voltages Vcon1˜Vconn to adjust the output power of the coupling signal Sc. Accordingly, the radio frequency circuit 600 may provide programmable loopback power control by adjusting the control voltages Vcon1˜Vconn corresponding to the transistors M1˜Mn.

In the embodiment of FIG. 6, in a bypass mode, the transistors M1˜Mn are turned on, and the signal S2 is transmitted from the terminal E2 to the terminal E3 through the coupling circuit 610. In addition, the signal S2 is not amplified by the low noise amplifier 630, the low noise amplifier 630 is disabled, and power amplifier 620 is disabled. Specifically, each of the transistors M1˜Mn may be regarded as a turned-on resistor in a turned-on state. As a result, in the bypass mode, the coupling circuit 610 may be used as a bypass circuit formed by multiple resistors connected in series. Thus, in the bypass mode (i.e., when the transistors M1˜Mn are all in the turned-on state), the signal S2 input by the antenna ant from the terminal E2 may pass through the coupling circuit 610 through the coupling terminal N1, and then be transmitted to the terminal E3 through the coupling terminal N2. In this way, the signal S2 may be transmitted to the control device 650 without being amplified by the low noise amplifier 630. It should be noted that the situation that the signal S2 is not amplified by the low noise amplifier 630 may include, for example: the signal S2 does not pass through the low noise amplifier 630, the amount of the signal S2 passing through the low noise amplifier 630 is much less than the amount of the signal S2 passing through the coupling circuit 610, or the low noise amplifier 630 is disabled. In addition, in the low noise amplification mode, the coupling mode, and the bypass mode, an enabling state or a disabling state of the power amplifier 620 and the low noise amplifier 630 may be, for example, controlled by the control device 650.

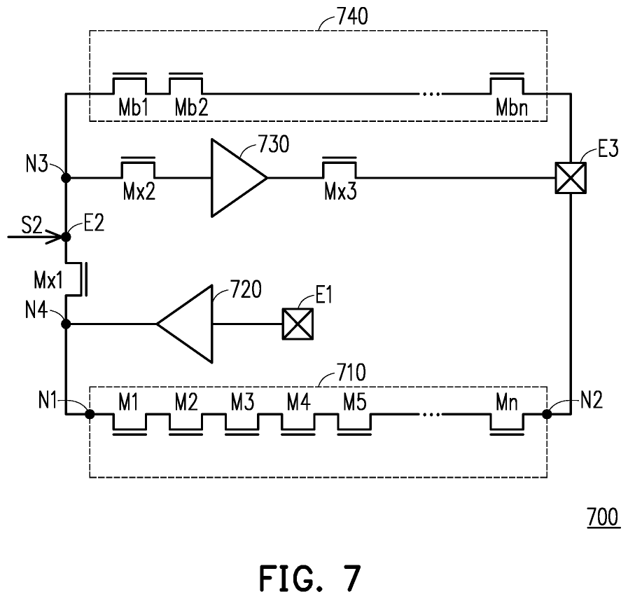

In another embodiment, the bypass circuit may also be additionally disposed as shown in FIG. 7, which is different from the overall structure of the coupling circuit 610. FIG. 7 is a schematic view of a radio frequency circuit 700 according to the sixth embodiment of the disclosure. The radio frequency circuit 700 in FIG. 7 is, for example, a front-end module. Referring to FIG. 7, a coupling circuit 710, a power amplifier 720, and a low noise amplifier 730 in the radio frequency circuit 700 are similar to the coupling circuit 610, the power amplifier 620, and the low noise amplifier 630 in FIG. 6. The radio frequency circuit 700 further includes a bypass circuit 740, and transistors Mx1, Mx2, and Mx3. The bypass circuit 740 includes multiple transistors Mb1˜Mbn. The bypass circuit 740 is coupled between the terminal E2 and the terminal E3. The transistor Mx1 is coupled between the coupling terminal N1 and the terminal E2. The transistor Mx2 is coupled between the terminal E2 and an input terminal of the low noise amplifier 730. The transistor Mx3 is coupled between an output terminal of the low noise amplifier 730 and the terminal E3. In this embodiment, the transistors Mx1, Mx2, and Mx3 may be used as switches. This embodiment may be, for example, used with the control device 650 in the front-end control system embodiment in FIG. 6 by using the control device 650 to control the transistors Mx1, Mx2 and Mx3 to be cut off or turned on respectively.

In the embodiment of FIG. 7, in the low noise amplification mode, the transistor Mx1 and the transistors Mb1˜Mbn are cut off, and the transistor Mx2 and the transistor Mx3 are turned on. Specifically, the signal S2 may be transmitted to the low noise amplifier 730 through the terminal E2. To further illustrate, the signal S2 input through the terminal E2 may be amplified by the low noise amplifier 730 and then received by the terminal E3 to ensure the receiving quality.

In the embodiment of FIG. 7, in the bypass mode, the transistor Mx1, the transistor Mx2, and the transistor Mx3 are cut off, and transistors Mb1˜Mbn are turned on. Specifically, the signal S2 may be transmitted from the terminal E2 to the terminal E3 through the bypass circuit 740, and the signal S2 is not amplified by the low noise amplifier 730. It should be noted that the situation that the signal S2 is not amplified by the low noise amplifier 730 may include, for example: the signal S2 does not pass through the low noise amplifier 730, the amount of the signal S2 passing through the low noise amplifier 730 is much less than the amount of the signal S2 passing through the bypass circuit 740, or the low noise amplifier 730 is disabled.

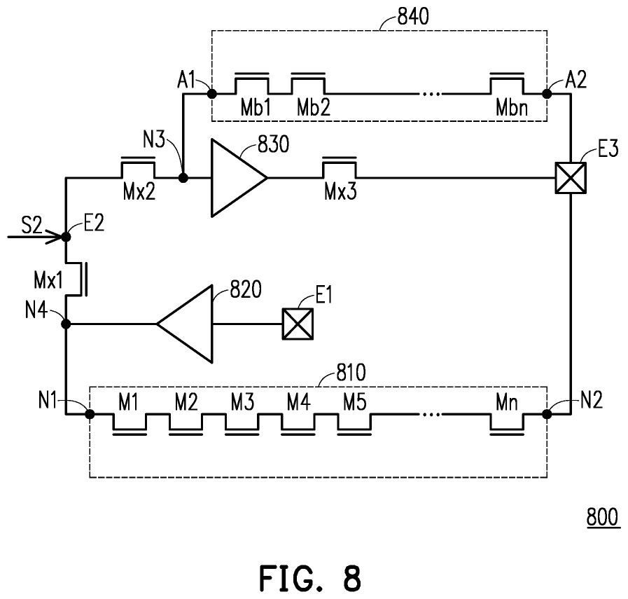

It is worth mentioning that the position of the transistor Mx2 in FIG. 7 (i.e., the switch between the terminal E2 and the low noise amplifier 730) is set behind a branch node N3 of the low noise amplifier 730 and the bypass circuit 740. In another embodiment, the position of the transistor Mx2 may be set ahead of the branch node N3 of the low noise amplifier 730 and the bypass circuit 740, as shown in FIG. 8. FIG. 8 is a schematic view of a radio frequency circuit 800 according to the seventh embodiment of the disclosure. The radio frequency circuit 800 in FIG. 8 is, for example, a front-end module. Referring to FIG. 8, a first terminal A1 of a bypass circuit 840 is coupled between the transistor Mx2 and an input terminal of a low noise amplifier 830, and a second terminal A2 of the bypass circuit 840 is coupled to the third terminal E3.

In the embodiment of FIG. 8, in the low noise amplification mode, the transistor Mx1 and the transistors Mb1˜Mbn are cut off, and the transistor Mx2 and the transistor Mx3 are turned on. Specifically, the signal S2 may be transmitted to the low noise amplifier 830 through the terminal E2. To further illustrate, the signal S2 input through the terminal E2 may be amplified by the low noise amplifier 830 and then received by the terminal E3 to ensure the receiving quality.

In the embodiment of FIG. 8, in the bypass mode, the transistor Mx1 and the transistor Mx3 are cut off, and the transistor Mx2 and the transistors Mb1˜Mbn are turned on. Specifically, the signal S2 may be transmitted from the terminal E2 to the terminal E3 through the bypass circuit 840, and the signal S2 is not amplified by the low noise amplifier 830. It should be noted that the situation that the signal S2 is not amplified by the low noise amplifier 830 may include, for example: the signal S2 does not pass through the low noise amplifier 830, the amount of the signal S2 passing through the low noise amplifier 830 is much less than the amount of the signal S2 passing through the bypass circuit 840, or the low noise amplifier 830 is disabled.

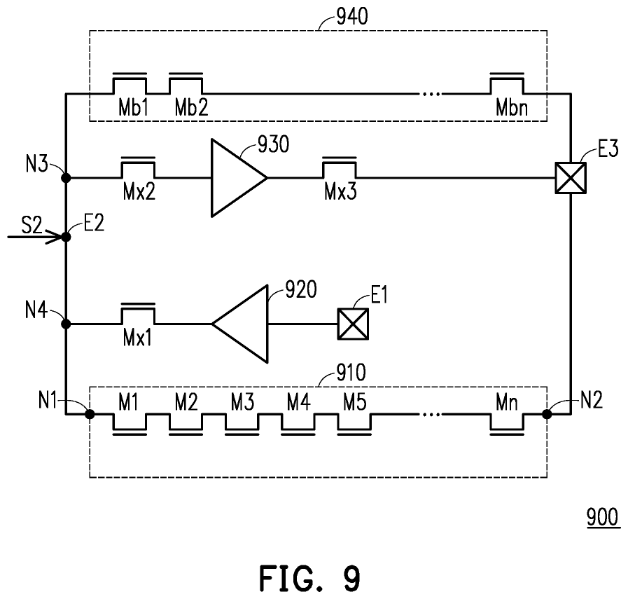

It is worth mentioning that, referring to FIG. 7 again, the position of the transistor Mx1 in FIG. 7 (i.e., the switch between the terminal E2 and the power amplifier 720) is set ahead of a branch node N4 of the power amplifier 720 and the coupling circuit 710. In another embodiment, the position of the transistor Mx1 may be set behind the branch node N4 of the power amplifier 720 and the coupling circuit 710, as shown in FIG. 9. FIG. 9 is a schematic view of a radio frequency circuit 900 according to the eighth embodiment of the disclosure. The radio frequency circuit 900 in FIG. 9 is, for example, a front-end module. Referring to FIG. 9, a coupling circuit 910, a power amplifier 920, and a low noise amplifier 930 in the radio frequency circuit 900 are similar to the coupling circuit 610, the power amplifier 620, and the low noise amplifier 630 in FIG. 6. The radio frequency circuit 900 further includes a bypass circuit 940, a transistor Mx1, a transistor Mx2, and a transistor Mx3. The bypass circuit 940 includes multiple transistors Mb1˜Mbn. The bypass circuit 940 is coupled between the terminal E2 and the terminal E3. The transistor Mx1 is coupled between an output terminal of the power amplifier 920 and the terminal E2. The transistor Mx2 is coupled between the terminal E2 and an input terminal of the low noise amplifier 930. The transistor Mx2 is coupled between an output terminal of the low noise amplifier 930 and the terminal E3.

In the embodiment of FIG. 9, in the low noise amplification mode, the transistor Mx1, the transistors M1˜Mn, and the transistors Mb1˜Mbn are cut off, and the transistor Mx2 and the transistor Mx3 are turned on. Specifically, the signal S2 may be transmitted to the low noise amplifier 930 through the terminal E2. To further illustrate, the signal S2 input through the terminal E2 may be amplified by the low noise amplifier 930 and then received by the terminal E3 to ensure the receiving quality.

In the embodiment shown in FIG. 9, in the bypass mode, the transistor Mx1, the transistor Mx2, the transistor Mx3, and the transistors M1˜Mn are cut off, and the transistors Mb1˜Mbn are turned on. Specifically, the signal S2 may be transmitted from the terminal E2 to the terminal E3 through the bypass circuit 940, and the signal S2 is not amplified by the low noise amplifier 930. It should be noted that the situation that the signal S2 is not amplified by the low noise amplifier 930 may include, for example: the signal S2 does not pass through the low noise amplifier 930, the amount of the signal S2 passing through the low noise amplifier 930 is much less than the amount of the signal S2 passing through the bypass circuit 940, or the low noise amplifier 930 is disabled.

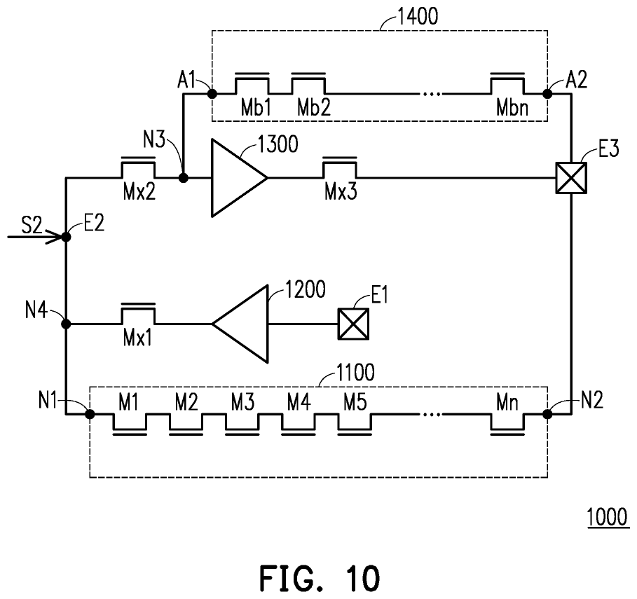

In addition, the position of the transistor Mx2 in FIG. 9 (i.e., the switch between the terminal E2 and the low noise amplifier 930) is set behind a branch node N3 of the low noise amplifier 930 and the bypass circuit 940. In another embodiment, the position of the transistor Mx2 may be set ahead of the branch node N3 of the low noise amplifier 930 and the bypass circuit 940, as shown in FIG. 10. FIG. 10 is a schematic view of a radio frequency circuit 1000 according to the ninth embodiment of the disclosure. The radio frequency circuit 1000 in FIG. 10 is, for example, a front-end module. Referring to FIG. 10, a first terminal A1 of a bypass circuit 1400 is coupled between the transistor Mx2 and an input terminal of a low noise amplifier 1300, and a second terminal A2 of the bypass circuit 1400 is coupled to the third terminal E3.

In the embodiment of FIG. 10, in the low noise amplification mode, the transistor Mx1, the transistors M1˜Mn, and the transistors Mb1˜Mbn are cut off, and the transistor Mx2 and the transistor Mx3 are turned on. Specifically, the signal S2 may be transmitted to the low noise amplifier 1300 through the terminal E2. To further illustrate, the signal S2 input through the terminal E2 may be amplified by the low noise amplifier 1300 and then received by the terminal E3 to ensure the receiving quality.

In the embodiment of FIG. 10, in the bypass mode, the transistor Mx1, the transistor Mx3, and the transistors M1˜Mn are cut off, and the transistor Mx2 and the transistors Mb1˜Mbn are turned on. Specifically, the signal S2 may be transmitted from the terminal E2 to the terminal E3 through the bypass circuit 1400, and the signal S2 is not amplified by the low noise amplifier 1300. It should be noted that the situation that the signal S2 is not amplified by the low noise amplifier 1300 may include, for example: the signal S2 does not pass through the low noise amplifier 1300, the amount of the signal S2 passing through the low noise amplifier 1300 is much less than the amount of the signal S2 passing through the bypass circuit 1400, or the low noise amplifier 1300 is disabled.

To sum up, the radio frequency circuit of the disclosure may use at least one transistor as a coupling circuit between the first coupling terminal and the second coupling terminal. The at least one transistor may be used as a shut-off capacitor in the cut-off state. Accordingly, the coupling circuit may achieve capacitive coupling in series by setting the at least one transistor to a state where at least a portion is cut off. In this way, the coupling circuit of the disclosure may replace the conventional coupling line, reducing the wiring length and power loss and improving the coupling directivity. In addition, compared with the conventional coupling line, in response to the coupling circuit of the disclosure being applied to the front-end module, the integrated circuit used together may save the pin for the coupling line, making the pin configuration more flexible and further reducing the volume of the integrated circuit package. Further, in the coupling mode, compared with the conventional coupling line, a cut-off degree of each of the at least one transistor is changed according to a control voltage to adjust the output power of the coupling signal. In this way, the radio frequency circuit of the disclosure may implement simpler and more diverse control methods, providing programmable loopback power control.

What is claimed is:

1. A radio frequency circuit, comprising:
a first terminal;
a second terminal;
a power amplifier, coupled between the first terminal and the second terminal, and configured to receive a first signal; and
a coupling circuit, comprising:
a first coupling terminal, coupled to the power amplifier and the second terminal;
a second coupling terminal; and
at least one transistor, connected in series between the first coupling terminal and the second coupling terminal,
wherein in a coupling mode, the at least one transistor is at least in an at least partial cut-off state, and the at least one transistor provides a coupling signal at the second coupling terminal through capacitive coupling,
wherein the first signal is controlled according to the coupling signal.

2. The radio frequency circuit according to claim 1, wherein output power of the coupling signal is positively correlated with output power of the first signal.

3. The radio frequency circuit according to claim 2, further comprising:
a control device, coupled between the first terminal and the second coupling terminal, and configured to receive the coupling signal and output the first signal to the power amplifier through the first terminal according to the coupling signal,
wherein the output power of the first signal is controlled according to the coupling signal, and the first signal is output through the second terminal after the output power of the first signal is amplified by the power amplifier.

4. The radio frequency circuit according to claim 1, wherein in the coupling mode, a cut-off degree of each of the at least one transistor is changed according to a control voltage to adjust the output power of the coupling signal.

5. The radio frequency circuit according to claim 1, wherein in the coupling mode, the at least one first transistor is cut off.

6. The radio frequency circuit according to claim 1, wherein an amount of the at least one transistor is plural, and each of the transistors is controlled according to an individual independent control voltage.

7. The radio frequency circuit according to claim 6, wherein in the coupling mode, N transistors among the transistors are cut off, N is a positive integer greater than 1, and output power of the coupling signal is changed based on N.

8. The radio frequency circuit according to claim 1, wherein an amount of the at least one transistor is at least 5.

9. The radio frequency circuit according to claim 1, further comprising:
a first capacitor, connected in series between the first coupling terminal and the at least one transistor; and
a second capacitor, connected in series between the second coupling terminal and the at least one transistor.

10. The radio frequency circuit according to claim 1, wherein the coupling circuit further comprises:
a shunt transistor, wherein a first terminal of the shunt transistor is coupled between the first coupling terminal and the second coupling terminal, wherein a second terminal of the shunt transistor is coupled to a reference voltage terminal,
wherein in the coupling mode, the shunt transistor is cut off.

11. The radio frequency circuit according to claim 10, wherein in a shut-off mode, the at least one transistor is cut off, and the shunt transistor is turned on.

12. The radio frequency circuit according to claim 1, wherein the power amplifier comprises:
a first stage amplifier; and
a second stage amplifier, wherein the first coupling terminal is coupled between the first stage amplifier and the second stage amplifier.

13. The radio frequency circuit according to claim 1, further comprising:
a third terminal; and
a low noise amplifier, coupled between the second terminal and the third terminal;
wherein in a low noise amplification mode, the at least one transistor is cut off, and a second signal is transmitted from the second terminal to the low noise amplifier.

14. The radio frequency circuit according to claim 13, wherein in a bypass mode, the at least one transistor is turned on, the second signal is transmitted from the second terminal to the third terminal through the coupling circuit, and the second signal is not amplified by the low noise amplifier.

15. The radio frequency circuit according to claim 13, wherein in the low noise amplification mode, the low noise amplifier is enabled and the power amplifier is disabled, and in the coupling mode, the low noise amplifier is disabled and the power amplifier is enabled.

16. The radio frequency circuit according to claim 13, wherein in a bypass mode, the low noise amplifier is disabled and the power amplifier is disabled.

17. The radio frequency circuit according to claim 13, further comprising:
a bypass circuit, coupled between the second terminal and the third terminal and comprising a plurality of transistors, in a bypass mode, the second signal is transmitted from the second terminal to the third terminal through the bypass circuit, and the second signal is not amplified by the low noise amplifier;
a first transistor, coupled between the first coupling terminal and the second terminal;
a second transistor, coupled between the second terminal and an input terminal of the low noise amplifier; and
a third transistor, coupled between an output terminal of the low noise amplifier and the third terminal.

18. The radio frequency circuit according to claim 17, wherein a first terminal of the bypass circuit is coupled between the second transistor and the input terminal of the low noise amplifier, and a second terminal of the bypass circuit is coupled to the third terminal.

19. The radio frequency circuit according to claim 13, further comprising:
a bypass circuit, coupled between the second terminal and the third terminal and comprising a plurality of transistors, in a bypass mode, the second signal is transmitted from the second terminal to the third terminal through the bypass circuit, and the second signal is not amplified by the low noise amplifier;
a first transistor, coupled between an output terminal of the power amplifier and the second terminal;
a second transistor, coupled between the second terminal and an input terminal of the low noise amplifier; and
a third transistor, coupled between an output terminal of the low noise amplifier and the third terminal.

20. The radio frequency circuit according to claim 19, wherein a first terminal of the bypass circuit is coupled between the second transistor and the input terminal of the low noise amplifier, and a second terminal of the bypass circuit is coupled to the third terminal.
